(19) United States
(12) Patent Application Publication
(10) Pub. No.: US 2023/0411398 A1
(43) Pub. Date: Dec. 21, 2023

(54) SEMICONDUCTOR STRUCTURE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventors: Haiyang ZHANG, Shanghai (CN); Bo SU, Shanghai (CN); Xingyu XIAO, Shanghai (CN)

(21) Appl. No.: 18/038,066

(22) PCT Filed: Nov. 24, 2020
(86) PCT No.: PCT/CN2020/130979

§ 371 Date: May 22, 2023

(51) Int. Cl. H01L 27/12; H01L 21/84

(52) U.S. Cl. CPC H01L 27/1203; H01L 27/1207; H01L 21/84; H01L 21/8221

(57) ABSTRACT

Semiconductor structure and formation method are provided. A method of forming a semiconductor structure includes providing a dielectric layer on a substrate, the dielectric layer including a first region and a second region under the first region, the first region including discrete first initial nanowires, and the second region including discrete second initial nanowires; etching the dielectric layer and the first initial nanowires in the first region to form a first opening in the first region, and forming first nanowires from the first initial nanowires; etching the dielectric layer at a bottom of the first opening and the second initial nanowires to form a second opening in the second region, and forming second nanowires from the second initial nanowires; forming a second source/drain layer in the second opening; forming an isolation layer on the second source/drain layer; and forming a first source/drain layer in the first opening.

### TECHNICAL FIELD

The present disclosure generally relates to the field of semiconductor manufacturing and, more particularly, relates to a semiconductor structure and a fabrication method thereof.

### BACKGROUND

As the semiconductor industry enters nanotechnology process nodes for higher device density, higher performance, and lower cost, challenges from fabrication and design issues have given rise to the development of three-dimensional designs for multi-gate field-effect transistors.

Conventional FinFET (fin field-effect transistor) has limitation in further increasing the working current. For example, since only the region close to the top surface and the sidewall of the fin is used as the channel region, the volume of the fin used as the channel region is relatively small, which may cause limitation in increasing the working current of FinFET. Therefore, the FinFET with a gate-all-around (GAA) structure is developed, which may increase the volume used as the channel region and further increase the working current of the FinFET with the GAA structure.

Based on developed FinFET with the GAA structure, in order to further increase the device density, a complementary fin field-effect transistor (CFET) with multiple GAA pairs vertically stacked one over another is developed. For the layout of CFET, an N-type GAA may be disposed above or below a P-type GAA, and the N-type GAA and P-type GAA of such stacked pair may pass through and cover the gate of each channel region, which may further reduce the area of the integrated circuit.

However, the performance of CFETs formed by existing processes may be still poor.

### SUMMARY

The technical solution provided by the present disclosure is to provide a semiconductor structure and a fabrication method of the semiconductor structure to improve the performance of the semiconductor structure.

In order to solve above technical problem, the technical solution of the present disclosure provides a semiconductor structure. The semiconductor structure includes a substrate, wherein a dielectric layer is on the substrate; the dielectric layer includes a second region and a first region on the second region; the first region includes a plurality of discrete first nanowires; and the second region includes a plurality of discrete second nanowires; a first opening in the first region and a first source/drain layer in the first opening; a second opening in the second region and a second source/drain layer in the second opening; and an isolation layer between the first source/drain layer and the second source/drain layer.

Optionally, a first nanowire and a second nanowire extend along a first direction.

Optionally, along the first direction, the first opening is between adjacent first nanowires.

Optionally, along the first direction, the second opening is between adjacent second nanowires.

Optionally, the first source/drain layer include first ions, the second source/drain layer includes second ions, and a conductivity type of the first ions is opposite to a conductivity type of the second ions.

Optionally, the plurality of first nanowires includes third ions, the plurality of second nanowires includes fourth ions, a conductivity type of the third ions is opposite to a conductivity type of the fourth ions, the conductivity type of the third ions is opposite to the conductivity type of the first ions, and the conductivity type of the fourth ions is opposite to the conductivity type of the second ions.

Optionally, a material of the first source/drain layer includes silicon phosphide, silicon, silicon carbide or silicon oxygen carbide; and a material of the second source/drain layer includes silicon germanium or germanium.

Optionally, a material of the first source/drain layer includes silicon germanium or germanium; and a material of the second source/drain layer includes silicon phosphide, silicon, silicon carbide or silicon oxygen carbide.

Optionally, a material of the dielectric layer includes silicon oxide, silicon nitride, silicon carbon nitride, silicon boron nitride, silicon oxygen carbon nitride or silicon oxygen nitride.

Optionally, a material of the isolation layer includes silicon oxide, silicon nitride, silicon carbon nitride, silicon boron nitride, silicon oxygen carbon nitride or silicon oxygen nitride.

Optionally, a thickness range of the isolation layer is from 10 angstroms to 100 angstroms.

Optionally, along a direction perpendicular to a sidewall of the first opening, the first opening has a first width; along a direction perpendicular to a sidewall of the second opening, the second opening has a second width; and the second width is less than the first width.

Optionally, the substrate further includes two source/drain regions arranged along the first direction, and a gate region between the two source/drain regions; and the first nanowire and the second nanowire are in the gate region.

Optionally, the structure further includes a gate structure on the gate region, wherein the gate structure surrounds the first nanowire and the second nanowire; the gate structure extends along a second direction; and the second direction is perpendicular to the first direction.

Correspondingly, the technical solution of the present disclosure further provides a fabrication method of a semiconductor structure. The method includes providing a substrate, wherein a dielectric layer is on the substrate; the dielectric layer includes a second region and a first region on the second region; the first region includes a plurality of discrete first initial nanowires; and the second region includes a plurality of discrete second initial nanowires; etching the dielectric layer and the plurality of first initial nanowires in the first region to form a first opening in the first region, and forming a plurality of first nanowires from the plurality of first initial nanowires; etching the dielectric layer at a bottom of the first opening and the plurality of second initial nanowires to form a second opening in the second region, and forming a plurality of second nanowires from the plurality of second initial nanowires; forming a second source/drain layer in the second opening; forming an isolation layer on a surface of the second source/drain layer; and forming a first source/drain layer in the first opening.

Optionally, a first nanowire and a second nanowire extend along a first direction.

Optionally, along the first direction, the first opening is between adjacent first nanowires.

Optionally, along the first direction, the second opening is between adjacent second nanowires.

Optionally, an etching method of the dielectric layer and the plurality of first initial nanowires in the first region includes forming a pattern layer on a surface of the dielectric layer, wherein the pattern layer exposes a part of the surface of the dielectric layer; and using the pattern layer as a mask, etching the dielectric layer and the plurality of first initial nanowires in the dielectric layer, until a surface of the dielectric layer in the second region is exposed, to form the first opening in the first region; and forming the plurality of first nanowires from the plurality of first initial nanowires.

Optionally, the method further includes, after forming the first opening and before forming the second opening, forming a protection layer on a sidewall surface of the first opening, wherein a material of the protection layer is different from a material of the dielectric layer; and after forming the second source/drain layer and before forming the first source/drain layer, removing the protection layer.

Optionally, a forming method of the protection layer includes forming a protection material film on the sidewall surface and a bottom surface of the first opening; and etching back the protection material film until the bottom surface of the first opening is exposed to form the protection layer.

Optionally, a material of the protection layer includes silicon oxide, silicon nitride, silicon carbon nitride, silicon boron nitride, silicon oxygen carbon nitride or silicon oxygen nitride.

Optionally, a material of the dielectric layer includes silicon oxide, silicon nitride, silicon carbon nitride, silicon boron nitride, silicon oxygen carbon nitride or silicon oxygen nitride.

Optionally, for a process of etching the dielectric layer at the bottom of the first opening and the plurality of second initial nanowires, an etching rate of the protection layer is lower than an etching rate of the dielectric layer, and the etching rate of the protection layer is lower than an etching rate of the plurality of second initial nanowires.

Optionally, the process of etching the dielectric layer at the bottom of the first opening and the plurality of second initial nanowires is a dry etching process.

Optionally, forming the isolation layer on the surface of the second source/drain layer includes forming an isolation material film in the first opening and on the surface of the dielectric layer; planarizing the isolation material film until the dielectric layer is exposed to form an initial isolation layer; and after a planarization process, etching the initial isolation layer to form the isolation layer.

Optionally, forming the second source/drain layer in the second opening includes forming a second epitaxial layer in the second opening by using a selective epitaxial growth process; and doping second ions into the second epitaxial layer to form the second source/drain layer.

Optionally, forming the first source/drain layer in the first opening includes forming a first epitaxial layer in the first opening by using a selective epitaxial growth process; and doping first ions into the first epitaxial layer to form the first source/drain layer.

Optionally, the substrate further includes two source/drain regions arranged along the first direction, and a gate region between the two source/drain regions; and the first nanowire and the second nanowire are in the gate region.

Optionally, the method further includes before forming the second source/drain layer, forming a gate structure on the gate region, wherein the gate structure surrounds the first nanowire and the second nanowire; the gate structure extends along a second direction; and the second direction is perpendicular to the first direction.

Compared with the existing technology, the technical solution of the present disclosure has following beneficial effects.

In the semiconductor structure provided by the technical solution of the present disclosure, the first source/drain layer is in the first opening, and the first opening is used to limit the volume of the first source/drain layer; the second source/drain layer is in the second opening, and the second opening is used to limit the volume of the second source/drain layer; and the first opening and the second opening make the volume difference between the first source/drain layer and the second source/drain layer within a controllable range to satisfy process requirement.

Furthermore, the isolation layer is between the first source/drain layer and the second source/drain layer; and the material of the isolation layer is an insulation material, which may electrically isolate the first source/drain layer and the second source/drain layer, so that an effective complementary fin field effect transistor is formed between the first region and the second region.

Furthermore, the thickness range of the isolation layer is from 10 angstroms to 100 angstroms. The significance of selecting the thickness range is that if the thickness is less than 10 angstroms, excessively thin isolation layer cannot sufficiently isolate the first source/drain layer and the second source/drain layer formed subsequently, and the performance of the semiconductor structure formed may be still poor; and if the thickness is greater than 100 angstroms, the space occupied by excessively thick isolation layer may be relatively large under the condition that desirable isolation effect can be ensured, such that he volumes of the first source/drain layer and the second source/drain layer may be relatively low, which may not be beneficial for improving the integration of integrated circuit and increasing driving current.

For the fabrication method of the semiconductor structure according to the technical solution of the present disclosure, by forming the first opening in the first region and forming the second opening in the second region, the first opening may provide space for forming the first source/drain layer to limit the volume of the first source/drain layer, and the second opening may provide space for forming the second source/drain layer to limit the volume of the second source/drain layer. The first opening and the second opening may make the volume difference between the first source/drain layer and the second source/drain layer within a controllable range to satisfy process requirement.

Furthermore, the fabrication method of the semiconductor structure further includes that after forming the first opening and before forming the second opening, forming the protection layer on the sidewall surface of the first opening, where the protection layer covers the first nanowires exposed by the sidewall of the first opening. On the one hand, the surface of the first nanowires is protected, which avoids that subsequent etching process to form the second opening causes etch damage on the first nanowires, thereby improving the performance of the semiconductor structure. On the other hand, the first nanowires is covered by the protection layer, which may avoid that, in the process of forming the second source/drain layer in the second opening, the second source/drain layer is epitaxially grown, using exposed surface of the first nanowires as a seed layer, to form the second source/drain layer in the second opening. Therefore, interference may not be between the first nanowires at the first region and the second nanowires at the second region.

Furthermore, the isolation layer is between the first source/drain layer and the second source/drain layer; and the material of the isolation layer is an insulation material, which may electrically isolate the first source/drain layer and the second source/drain layer, so that an effective complementary fin field effect transistor is formed between the first region and the second region.

### BRIEF DESCRIPTION OF THE DRAWINGS

FIGS. 1-12 illustrate structural schematics corresponding to certain stages of a fabrication method of a semiconductor structure according to embodiments of the present disclosure.

### DETAILED DESCRIPTION

As mentioned in the background technology, in order to realize the complementary FinFET with multiple vertically stacked GAA pairs, the area of the integrated circuit may be further reduced. However, the performance of conventionally formed complementary FinFET may be still poor.

In order to solve above problems, the technical solutions of the present disclosure provide a semiconductor structure and a fabrication method of the semiconductor structure. The method includes firstly etching the dielectric layer and the first initial nanowires in the first region to form the first opening in the first region; etching the dielectric layer at the bottom of the first opening and the second initial nanowires to form the second opening in the second region; forming the second source/drain layer in the second opening; forming the isolation layer on the surface of the second source/drain layer; and forming the first source/drain layer in the first opening. The first opening provides space for the first source/drain layer, and the second opening provides space for the second source/drain layer. Therefore, the first opening and the second opening make the volume difference between the first source/drain layer and the second source/drain layer within a controllable range to satisfy process requirement.

In order to make above objectives, features and beneficial effects of the present disclosure more comprehensible, embodiments of the present disclosure are described in detail below in conjunction with accompanying drawings.

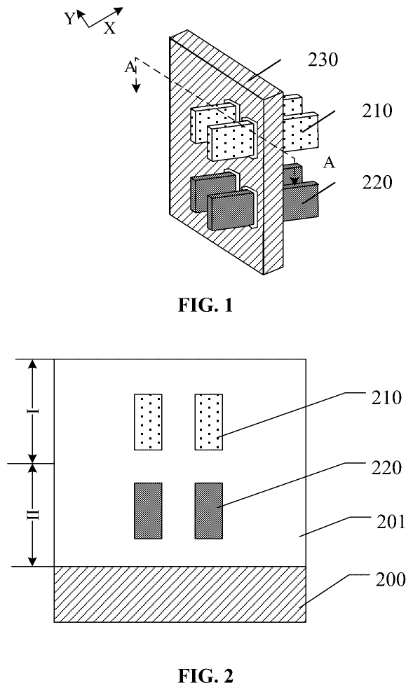

FIGS. 1-12 illustrate structural schematics corresponding to certain stages of a fabrication method of a semiconductor structure according to embodiments of the present disclosure.

Referring to FIGS. 1-2, FIG. 2 illustrates a cross-sectional view along an A-A direction in FIG. 1, and FIG. 1 illustrates a three-dimensional view omitting a dielectric layer and a substrate. A substrate 200 may be provided; a dielectric layer 201 may be on the substrate 200; the dielectric layer 201 may include a second region II and a first region I on the second region II; and the first region I may include a plurality of discrete first initial nanowires 210, and the second region II may include a plurality of discrete second initial nanowires 220.

The material of the substrate 200 may include a semiconductor material.

In one embodiment, the material of the substrate 200 may be silicon.

In other embodiments, the material of the substrate may include silicon carbide, silicon germanium, a multiple semiconductor material including III-V group elements, silicon-on-insulator (SOI), or germanium-on-insulator, where the multiple semiconductor material including III-V group elements may include InP, GaAs, GaP, InAs, InSb, InGaAs or InGaAsP.

In other embodiments, a device layer (not shown in drawings) may be included in the substrate. The device layer may include device structures such as PMOS transistors or NMOS transistors. The device layer may further include an interconnection structure electrically connected to the device structures, and an insulation layer surrounding the device structures and the interconnection structure.

The first initial nanowire 210 and the second initial nanowire 220 may extend along the first direction X.

In one embodiment, the materials of the first initial nanowire 110 and the second initial nanowire 120 may be silicon.

In other embodiments, the materials of the first initial nanowire and the second initial nanowire may include silicon carbide, silicon germanium, a multiple semiconductor material including III-V group elements, silicon-on-insulator (SOI), or germanium-on-insulator, where the multiple semiconductor material including III-V group elements may include InP, GaAs, GaP, InAs, InSb, InGaAs or InGaAsP.

In one embodiment, the first initial nanowire 210 may include third ions, the second initial nanowire 220 may include fourth ions, and the conductivity types of the third ions and the fourth ions may be opposite to each other.

For example, in one embodiment, the third ions may be N-type ions and include phosphorus ions, arsenic ions or antimony ions; and the fourth ions may be P-type ions and include boron ions, BF²⁻ ions or indium ions.

In other embodiments, the third ions may be P-type ions and include boron ions, BF²⁻ ions or indium ions; and the fourth ions may be N-type ions and include phosphorus ions, arsenic ions or antimony ions.

In one embodiment, the fabrication method of the first initial nanowires 210, the second initial nanowires 220, and the dielectric layer 201 may include forming the first material layer on the surface of the substrate 200 (not shown in drawings); forming a plurality of discrete second initial nanowires 220 on the surface of the first material layer; forming the second material layer (not shown in drawings) on the surface of the second initial nanowires 220 and the surface of the first material layer, where the top surface of the second material layer may be higher than the top surface of the first material layer; forming a plurality of discrete first initial nanowires 210 on the surface of the second material layer; and forming the third material layer (not shown in drawings) on the surface of the first initial nanowires 210 and the second material layer, where the top surface of the third material layer may be higher than the top surface of the first initial nanowires 210.

The first material layer, the second material layer, and the third material layer may form the dielectric layer 201.

In one embodiment, the material of the dielectric layer 201 may include silicon oxide.

In other embodiments, the material of the dielectric layer may include silicon nitride, silicon oxygen nitride, silicon oxide carbide, silicon nitrogen carbide, or silicon oxide nitrogen carbide.

The substrate 200 may further include two source/drain regions (not shown in drawings) along the first direction X, and a gate region (not shown in drawings) between two source/drain regions.

The fabrication method of the semiconductor structure may further include, before forming the second source/drain layer, forming a gate structure 230 on the gate region. The gate structure 230 may surround the first initial nanowires 210 and the second initial nanowires 220; the gate structure 230 may extend along the second direction Y; and the second direction Y may be perpendicular to the first direction X.

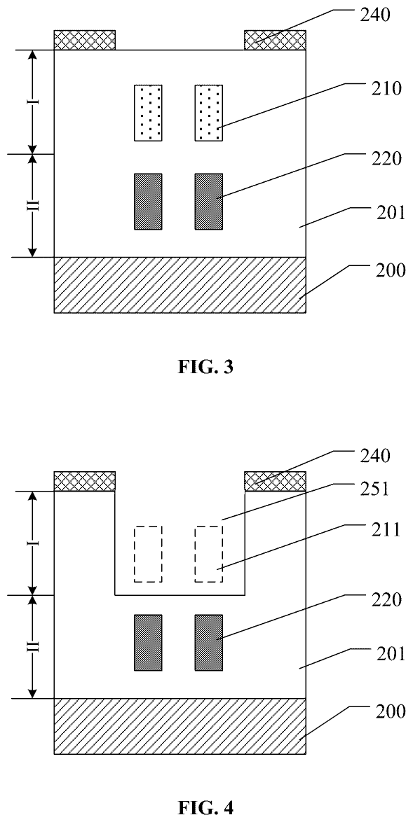

Next, the dielectric layer 201 and the first initial nanowires at the first region I may be etched to form the first opening in the first region I, and the first nanowires may be formed from the first initial nanowires 210. The process of forming the first opening and the first nanowires refers to FIGS. 3-4.

Referring to FIG. 3, a pattern layer 240 may be formed on the surface of the dielectric layer 201; and the pattern layer 240 may expose a part of the surface of the dielectric layer 201.

The pattern layer 240 may be used as a mask for subsequently etching the dielectric layer 201 at the first region I.

For example, the pattern layer 240 may include a pattern (not shown in drawings), which may expose the surface of the dielectric layer 201 on the first initial nanowires 210 on the source/drain region.

The material of the pattern layer 240 may include a hard mask material or photoresist. In one embodiment, the material of the pattern layer 240 may be photoresist.

Referring to FIG. 4, using the pattern layer 240 as the mask, the dielectric layer 201 and the first initial nanowires 210 in the dielectric layer 201 may be etched until the surface of the dielectric layer 201 at the first region I is exposed, and the first opening 251 may be formed in the first region I, such that the first nanowires 211 may be formed from the first initial nanowires 210.

The first opening 251 may provide space for subsequent formation of the first source/drain layer, thereby limiting the volume of the first source/drain layer.

Since the first initial nanowires 210 extend along the first direction X, the first nanowires 211 formed by etching a part of the first initial nanowires 210 may extend along the first direction X.

For example, along the first direction X, the first opening 251 may be between adjacent first nanowires 211.

The process of etching the dielectric layer 201 and the first initial nanowires 210 in the dielectric layer 201 may include one or two combinations of a dry etching process and a wet etching process.

In one embodiment, the process of etching the dielectric layer 201 and the first initial nanowires 210 in the dielectric layer 201 may be a dry etching process, which may be beneficial for improving morphology of formed first opening 251; and the sidewall of the first opening 251 may be desirably perpendicular to the bottom of the first opening 251, and morphology of formed first nanowires 211 may be desirable, which may be beneficial for improving performance of the semiconductor structure formed.

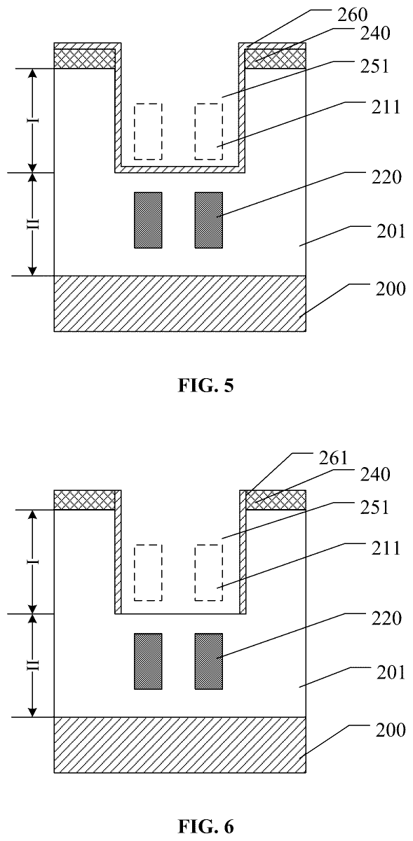

Next, a protection layer may be formed on the surface of the sidewall of the first opening 251, and the material of the protection layer may be different from the material of the dielectric layer. The process for forming the protection layer refers to FIGS. 5-6.

Referring to FIG. 5, a protection material film 260 may be formed on the sidewall surface and the bottom surface of the first opening 251.

The protection material film 260 may provide a material layer for subsequent formation of the protection layer.

In one embodiment, the protection material film 260 may also be on the surface of the dielectric layer 201 and the surface of the pattern layer 240.

The material of the protection material film 260 may be different form the material of the dielectric layer 201.

In one embodiment, the material of the protection material film 260 may be silicon nitride. In other embodiments, the material of the protection material film may include silicon oxide, silicon carbon nitride, silicon boron nitride, silicon oxygen carbon nitride, or silicon oxygen nitride.

The process for forming the protection material film 260 may include a chemical vapor deposition process, a physical vapor deposition process, or an atomic layer deposition process.

In one embodiment, the process for forming the protection material film 260 may be an atomic layer deposition process. The protection material film 260 formed by the atomic layer deposition process may have desirable density and high quality, such that the protection layer may desirably protect the dielectric layer 201 on the sidewall of the first opening 251 and the first nanowires 211 subsequently.

Referring to FIG. 6, the protection material film 260 may be etched back until the bottom surface of the first opening 251 is exposed to form a protection layer 261.

Since the protection layer 261 is formed be etching the protection material film 260, correspondingly, the material of the dielectric layer 201 may be different form the material of the protection layer 261. In one embodiment, the material of the protection layer 261 may be silicon nitride. In other embodiments, the material of the protection layer may include silicon oxide, silicon carbon nitride, silicon boron nitride, silicon oxygen carbon nitride, or silicon oxygen nitride.

By forming the protection layer 261 on the sidewall surface of the first opening 251, the protection layer 261 may cover the first nanowires 211 exposed by the sidewall of the first opening 251. On the one hand, the surface of the first nanowires 211 may be protected, which may avoid that subsequent etching process to form the second opening causes etch damage on the first nanowires 211, thereby improving the performance of the semiconductor structure. On the other hand, the first nanowires 211 may be covered by the protection layer 261, which may avoid that, in the process of forming the second source/drain layer in the second opening, the second source/drain layer may be epitaxially grown, using exposed surface of the first nanowires 211 as a seed layer, to form the second source/drain layer in the second opening. Therefore, interference may not be between the first nanowires 211 at the first region I and the second nanowires at the second region II.

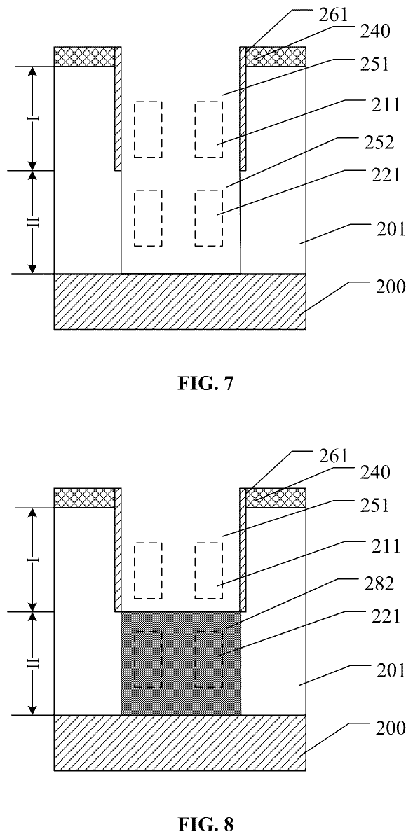

Referring to FIG. 7, after the protection layer 261 is formed, the dielectric layer 201 and the second initial nanowires 220 at the bottom of the first opening 251 may be etched to form a second opening 252 at the second region II; and the second nanowires 221 may be formed from the second initial nanowires 220.

The second opening 252 may provide space for subsequent formation of the second source/drain layer, thereby limiting the volume of the second source/drain layer.

In one embodiment, using the pattern layer 240 and the protection layer 261 as the mask, the dielectric layer 201 and the second initial nanowires 220 in the dielectric layer 201 may be etched.

Since the second initial nanowires 220 extend along the first direction X, the second nanowires 221 formed by etching a part of the second initial nanowires 220 may extend along the first direction X.

For example, along the first direction X, the second opening 252 may be between adjacent second nanowires 221.

Along the sidewall of the first opening 251, the first opening 251 may have the first width; and along the sidewall on the second opening 252, the second opening 252 may have the second width.

For the process of etching the dielectric layer 201 at the bottom of the first opening 251 and the second initial nanowires 220, the etching rate of the protection layer 261 may be less than the etching rate of the dielectric layer 201, and the etching rate of the protection layer 261 may be less than the etching rate of the second initial nanowire 220.

The process of etching the dielectric layer 201 at the bottom of the first opening 251 and the second initial nanowires 220 may include one or two combinations of a dry etching process and a wet etching process.

In one embodiment, the process of etching the dielectric layer 201 at the bottom of the first opening 251 and the second initial nanowires 220 may be a dry etching process, which may be beneficial for improving morphology of formed second opening 252; and the sidewall of the second opening 252 may be desirably perpendicular to the bottom of the second opening 252, and morphology of formed second nanowires 221 may be desirable, which may be beneficial for improving performance of the semiconductor structure formed.

Referring to FIG. 8, after forming the second opening 252 and the second nanowires 221, the second source/drain layer 282 may be formed within the second opening 252.

A second epitaxial layer may be formed in the second opening 252 by using a selective epitaxial growth process; second ions may be doped in the second epitaxial layer to form the second source/drain layer 282.

The second nanowires 221 may be used as a seed layer for forming a film layer to realize the formation of the second source/drain layer 282 in the second opening 252.

In one embodiment, after forming the second source/drain layer 282, the method may further include etching a part of the second source/drain layer 282 to reduce the height of the second source/drain layer 282. In such way, the height of the second source/drain layer 282 may satisfy process requirement. Meanwhile, etched second source/drain layer 282 may be in the second opening 252 to avoid subsequent contact with the first nanowires 211 on the sidewall of the first opening 251.

In one embodiment, the material of the second source/drain layer 282 may be silicon germanium; the second ions may be P-type ions; and the P-type ions may include boron ions, BF²⁻ ions or indium ions.

In other embodiments, the material of the second source/drain layer may be silicon phosphide; the second ions may be N-type ions; and the N-type ions may include phosphorus ions, arsenic ions or antimony ions.

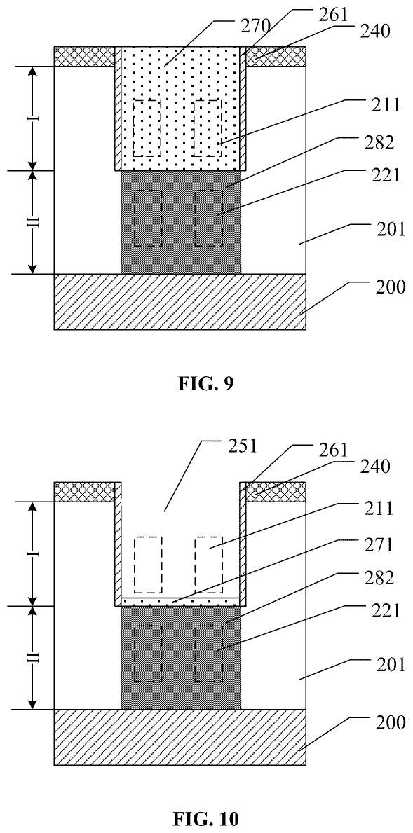

Next, an isolation layer may be formed on the surface of the second source/drain layer 282. The process of forming the isolation layer refers to FIGS. 9-10.

Referring to FIG. 9, an isolation material film may be formed in the first opening 251 and on the surface of the dielectric layer 201 (not shown in drawings), and the isolation material film may be planarized until the dielectric layer 201 is exposed to form an initial isolation layer 270.

The initial isolation layer 270 may provide a material layer for subsequent formation of the isolation layer.

In one embodiment, the material of the initial isolation layer 270 may be same as the material of the dielectric layer 201, and the material of the initial isolation layer 270 may be silicon oxide. In other embodiments, the material of the initial isolation layer may be different from the material of the dielectric layer.

For example, in one embodiment, the planarization process may stop until the surface of the pattern layer 240 on the dielectric layer 201 is exposed.

Referring to FIG. 10, after the planarization process, the initial isolation layer 270 may be etched to form an isolation layer 271.

The thickness range of the isolation layer 271 may be about 10 to 100 angstroms.

The significance of selecting the thickness range is that if the thickness is less than 10 angstroms, excessively thin isolation layer 271 cannot sufficiently isolate the first source/drain layer and the second source/drain layer 282 formed subsequently, and the performance of the semiconductor structure formed may be still poor; and if the thickness is greater than 100 angstroms, the space occupied by excessively thick isolation layer 271 may be relatively large under the condition that desirable isolation effect can be ensured, such that he volumes of the first source/drain layer and the second source/drain layer 282 may be relatively low, which may not be beneficial for improving the integration of integrated circuit and increasing driving current.

In one embodiment, the material of the isolation layer 271 may be different from the protection layer 261. The material of the isolation layer 271 may be silicon oxide.

In other embodiments, the material of the isolation layer may also include silicon nitride, silicon oxygen nitride, silicon oxide carbide, silicon nitrogen carbide, or silicon oxide nitrogen carbide.

In the process of etching the initial isolation layer 270, the etching rate of the protection layer 261 may be relatively small, such that the protection layer 261 can protect the dielectric layer 201 and the first nanowires 211 to avoid damage to the dielectric layer 201 and the first nanowires 211, thereby improving performance of formed semiconductor structure.

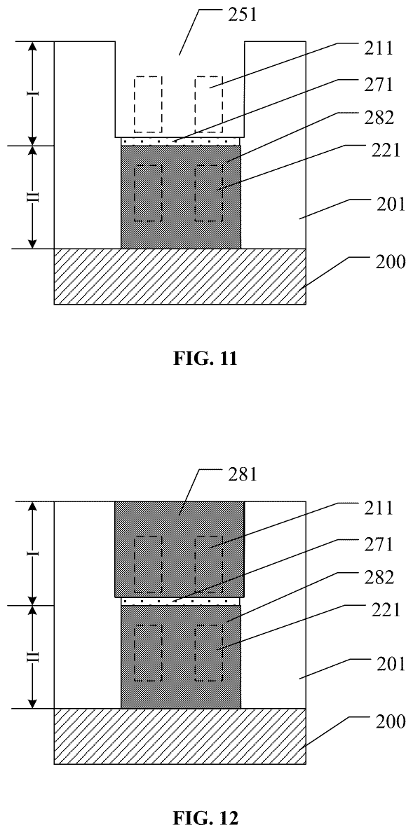

Referring to FIG. 11, after forming the second source/drain layer 282, the protection layer 261 may be removed.

In one embodiment, after the second source/drain layer 282 is formed and the isolation layer 271 is formed, the protection layer 261 may be removed.

In one embodiment, the method may further include, after forming the second source/drain layer 282, removing the pattern layer 240.

In other embodiments, after the second source/drain layer is formed and before the isolation layer is formed, the protection layer may be removed.

Referring FIG. 12, after forming the isolation layer 271, the first source/drain layer 281 may be formed in the first opening 251.

Using a selective epitaxial growth process, the first epitaxial layer (not shown in drawings) may be formed in the first opening 251; and first ions may be doped into the first epitaxial layer to form the first source/drain layer 281.

In one embodiment, after forming the isolation layer 271 and removing the protection layer 261, the first nanowires 211 may be exposed, and the first nanowires 211 may be used as a seed layer for forming a film layer to realize the formation of the first source/drain layer 281 in the first opening 251.

In other embodiments, after forming the first source/drain layer, the method may further include etching a part of the first source/drain layer to reduce the height of the first source/drain layer. The height of the first source/drain layer may satisfy process requirement.

For example, the first source/drain layer 281 may be on the surface of the isolation layer 271, and the isolation layer 271 may be between the first source/drain layer 281 and the second source/drain layer 282.

The isolation layer 271 may be between the first source/drain layer 281 and the second source/drain layer 282; and the material of the isolation layer 271 may be an insulation material, which may electrically isolate the first source/drain layer 271 and the second source/drain layer 282, so that a complementary fin field effect transistor may be formed between the first region I and the second region II.

The conductivity types of the first ions and the second ions may be opposite.

In one embodiment, the material of the first source/drain layer 281 may be silicon phosphide; the first ions may be N-type ions; and the N-type ions may include phosphorus ions, arsenic ions or antimony ions.

In other embodiments, the material of the first source/drain layer may be silicon germanium; the first ions may be P-type ions; and the P-type ions may include boron ions, BF²⁻ ions or indium ions.

By forming the first opening 251 in the first region I and forming the second opening 252 in the second region II, the first opening 251 may provide space for forming the first source/drain layer 281 to limit the volume of the first source/drain layer 281, and the second opening 252 may provide space for forming the second source/drain layer 282 to limit the volume of the second source/drain layer 282. The first opening 251 and the second opening 252 may make the volume difference between the first source/drain layer 281 and the second source/drain layer 282 within a controllable range to satisfy process requirement.

Correspondingly, embodiments of the present disclosure also provide a semiconductor structure formed by above-mentioned method. Referring to FIGS. 1 and 12, the semiconductor structure may include the substrate 200, where the dielectric layer 201 may be on the substrate 200, the dielectric layer 201 may include the second region II and the first region I on the second region II, the first region I may include the plurality of discrete first nanowires 211, and the second region II may include the plurality of discrete second nanowires 221; the first opening 251 in the first region I and the first source/drain layer 281 in the first opening 251; the second opening 252 in the second region II and the second source/drain layer 282 in the second opening 252; and the isolation layer 271 between the first source/drain layer 281 and the second source/drain layer 282.

The first source/drain layer 281 may be in the first opening 251, and the first opening 251 may be used to limit the volume of the first source/drain layer 281; and the second source/drain layer 282 may be in the second opening 252, and the second opening 252 may be used to limit the volume of the second source/drain layer 282. The first opening 251 (as shown in FIG. 7) and the second opening 252 (as shown in FIG. 7) may make the volume difference between the first source/drain layer 281 and the second source/drain layer 282 within a controllable range to satisfy process requirement.

Above-mentioned structure is described in detail in conjunction with drawings hereinafter.

The first nanowire 21 and the second nanowire 221 may extend along the first direction X.

Along the first direction X, the first opening 251 may be between adjacent first nanowires 211.

Along the first direction X, the second opening 252 may be between adjacent second nanowires 221.

The first source/drain layer 281 may include first ions, the second source/drain layer 282 may include second ions, and the conductivity types of the first ions and the second ions may be opposite.

The first nanowire 211 may include third ions, the second nanowire 221 may include fourth ions, the conductivity types of the third ions and the fourth ions may be opposite, the conductivity types of the third ions and the first ions may be opposite, and the conductivity types of the fourth ions and the second ions may be opposite.

In one embodiment, the first ions may be N-type ions and include phosphorus ions, arsenic ions or antimony ions; the second ions may be P-type ions and include boron ions, BF²⁻ ions or indium ions; the third ions may be P-type ions and include boron ions, BF²⁻ ions or indium ions; and the fourth ions may be N-type ions and include phosphorus ions, arsenic ions or antimony ions.

In other embodiments, the first ions may be P-type ions. The first ions may include.

In one embodiment, the material of the first source/drain layer 281 may include silicon phosphide, silicon, silicon carbide or silicon oxygen carbide; and the material of the second source/drain layer 282 may include silicon germanium or germanium.

In other embodiments, the material of the first source/drain layer may include silicon germanium or germanium; and the material of the second source and drain layer may include silicon phosphide, silicon, silicon carbide or silicon oxygen carbide.

The material of the dielectric layer 201 may include silicon oxide, silicon nitride, silicon carbon nitride, silicon boron nitride, silicon oxygen carbon nitride or silicon oxygen nitride.

The material of the isolation layer 271 may include silicon oxide, silicon nitride, silicon carbon nitride, silicon boron nitride, silicon oxygen carbon nitride or silicon oxygen nitride.

The thickness range of the isolation layer 271 may be about 10 to 100 angstroms.

The isolation layer 271 may be between the first source/drain layer 281 and the second source/drain layer 282; and the material of the isolation layer 271 may be an insulation material, which may electrically isolate the first source/drain layer 281 and the second source/drain layer 282, so that an effective complementary fin field effect transistor may be formed between the first region I and the second region II.

Along the direction perpendicular to the sidewall of the first opening 251, the first opening 251 may have the first width; along the direction perpendicular to the sidewall of the second opening 252, the second opening 252 may have second width; and the second width may be less than the first width.

The substrate 200 may further include two source/drain regions arranged along the first direction X, and the gate region between two source/drain regions; and the first nanowires 211 and the second nanowires 221 may be in the gate region.

The semiconductor structure may further include the gate structure 230 on the gate region. The gate structure 230 may surround the first nanowires 211 and the second nanowires 221; the gate structure 230 may extend along the second direction Y; and the second direction Y may be perpendicular to the first direction X.

Although the present disclosure has been disclosed above, the present disclosure may not be limited thereto. Any changes and modifications may be made by those skilled in the art without departing from the spirit and scope of the present disclosure, and the scope of the present disclosure should be determined by the scope defined by the appended claims.

1. A semiconductor structure, comprising:
a substrate;
a dielectric layer on the substrate, the dielectric layer including a first region and a second region under the first region, the first region including a plurality of discrete first nanowires and the second region including a plurality of discrete second nanowires;
a first source/drain layer in a first opening in the first region;
a second source/drain layer in a second opening in the second region; and
an isolation layer between the first source/drain layer and the second source/drain layer.

2. The structure according to claim 1, wherein:
a first nanowire and a second nanowire extend along a first direction.

3. The structure according to claim 2, wherein:
along the first direction, the first opening is between adjacent first nanowires; and/or
along the first direction, the second opening is between adjacent second nanowires.

4. (canceled)

5. The structure according to claim 1, wherein:
the first source/drain layer include first ions, the second source/drain layer includes second ions, and a conductivity type of the first ions is opposite to a conductivity type of the second ions; and/or
the plurality of first nanowires includes third ions, the plurality of second nanowires includes fourth ions, a conductivity type of the third ions is opposite to a conductivity type of the fourth ions, the conductivity type of the third ions is opposite to the conductivity type of the first ions, and the conductivity type of the fourth ions is opposite to the conductivity type of the second ions.

6. (canceled)

7. The structure according to claim 1, wherein:
a material of the first source/drain layer includes silicon phosphide, silicon, silicon carbide or silicon oxygen carbide; and a material of the second source/drain layer includes silicon germanium or germanium; or a material of the first source/drain layer includes silicon germanium or germanium; and a material of the second source/drain layer includes silicon phosphide, silicon, silicon carbide or silicon oxygen carbide; and/or
a material of the dielectric layer includes silicon oxide, silicon nitride, silicon carbon nitride, silicon boron nitride, silicon oxygen carbon nitride or silicon oxygen nitride; and/or
a material of the isolation layer includes silicon oxide, silicon nitride, silicon carbon nitride, silicon boron nitride, silicon oxygen carbon nitride or silicon oxygen nitride.

8. (canceled)

9. (canceled)

10. (canceled)

11. The structure according to claim 1, wherein:
a thickness range of the isolation layer is from 10 angstroms to 100 angstroms.

12. The structure according to claim 1, wherein:
along a direction perpendicular to a sidewall of the first opening, the first opening has a first width; along a direction perpendicular to a sidewall of the second opening, the second opening has a second width; and the second width is less than the first width.

13. The structure according to claim 2, wherein:
the substrate further includes two source/drain regions arranged along the first direction, and a gate region between the two source/drain regions; and the first nanowire and the second nanowire are in the gate region.

14. The structure according to claim 13, further including:
a gate structure on the gate region, wherein the gate structure surrounds the first nanowire and the second nanowire; the gate structure extends along a second direction; and the second direction is perpendicular to the first direction.

15. A fabrication method of a semiconductor structure, comprising:
providing a substrate, wherein a dielectric layer is on the substrate; the dielectric layer includes a second region and a first region on the second region; the first region includes a plurality of discrete first initial nanowires; and the second region includes a plurality of discrete second initial nanowires;
etching the dielectric layer and the plurality of first initial nanowires in the first region to form a first opening in the first region, and forming a plurality of first nanowires from the plurality of first initial nanowires;
etching the dielectric layer at a bottom of the first opening and the plurality of second initial nanowires to form a second opening in the second region, and forming a plurality of second nanowires from the plurality of second initial nanowires;
forming a second source/drain layer in the second opening;
forming an isolation layer on a surface of the second source/drain layer; and
forming a first source/drain layer in the first opening.

16. (canceled)

17. (canceled)

18. (canceled)

19. The method according to claim 15, wherein etching the dielectric layer and the plurality of first initial nanowires in the first region includes:
forming a pattern layer on a surface of the dielectric layer, wherein the pattern layer exposes a part of the surface of the dielectric layer; and
using the pattern layer as a mask, etching the dielectric layer and the plurality of first initial nanowires in the dielectric layer, until a surface of the dielectric layer in the second region is exposed, to form the first opening in the first region; and forming the plurality of first nanowires from the plurality of first initial nanowires.

20. The method according to claim 15, further including:
after forming the first opening and before forming the second opening, forming a protection layer on a sidewall surface of the first opening, wherein a material of the protection layer is different from a material of the dielectric layer; and
after forming the second source/drain layer and before forming the first source/drain layer, removing the protection layer.

21. The method according to claim 20, wherein forming the protection layer includes:
forming a protection material film on the sidewall surface and a bottom surface of the first opening; and
etching back the protection material film until the bottom surface of the first opening is exposed to form the protection layer.

22. The method according to claim 21, wherein:
a material of the protection layer includes silicon oxide, silicon nitride, silicon carbon nitride, silicon boron nitride, silicon oxygen carbon nitride or silicon oxygen nitride.

23. (canceled)

24. The method according to claim 20, wherein:
for a process of etching the dielectric layer at the bottom of the first opening and the plurality of second initial nanowires, an etching rate of the protection layer is lower than an etching rate of the dielectric layer, and the etching rate of the protection layer is lower than an etching rate of the plurality of second initial nanowires.

25. The method according to claim 24, wherein:
the process of etching the dielectric layer at the bottom of the first opening and the plurality of second initial nanowires is a dry etching process.

26. The method according to claim 15, wherein a forming the isolation layer on the surface of the second source/drain layer includes:
forming an isolation material film in the first opening and on the surface of the dielectric layer;
planarizing the isolation material film until the dielectric layer is exposed to form an initial isolation layer; and
after a planarization process, etching the initial isolation layer to form the isolation layer.

27. The method according to claim 15, wherein forming the second source/drain layer in the second opening includes:
forming a second epitaxial layer in the second opening by using a selective epitaxial growth process; and
doping second ions into the second epitaxial layer to form the second source/drain layer.

28. The method according to claim 15, wherein forming the first source/drain layer in the first opening includes:
forming a first epitaxial layer in the first opening by using a selective epitaxial growth process; and
doping first ions into the first epitaxial layer to form the first source/drain layer.

29. (canceled)

30. The method according to claim 29, further including:
before forming the second source/drain layer, forming a gate structure on the gate region, wherein the gate structure surrounds the first nanowire and the second nanowire; the gate structure extends along a second direction; and the second direction is perpendicular to the first direction.
